(19) United States
(12) Patent Application Publication
(10) Pub. No.: US 2011/0102979 A1
(43) Pub. Date: May 5, 2011

(54) ELECTRONIC DEVICE INCLUDING POP-OUT STYLUS

(75) Inventors: Nicholas Jinkinson, Reading (GB); Mark Janninck, Glen Ellyn, IL (US)

(73) Assignee: MOTOROLA, INC., Schaumburg, IL (US)

(21) Appl. No.: 12/611,479

(22) Filed: Nov. 3, 2009

(51) Int. Cl. H05K 5/00

(52) U.S. Cl. 361/679.01

(57) ABSTRACT

Embodiments of an electronic device for use in conjunction with a stylus are provided. In one embodiment, the electronic device includes a first housing and a stylus storage groove, which is formed in a surface of the first housing and which is configured to receive the stylus therein. The stylus storage groove enables the stylus to be inserted therein and removed therefrom along an axis substantially orthogonal to the longitudinal axis of the stylus.

### TECHNICAL FIELD

The present invention relates generally to electronic devices having touchscreen capabilities and, more particularly, to embodiments of an electronic device that provides an improved means for stylus storage.

### BACKGROUND

Smart phones, personal digital assistants, personal organizers, satellite navigation systems, portable gaming systems, and other handheld electronic devices are increasingly being equipped with touchscreens, which enable a user to input data by contacting target areas of the touchscreen panel with his or her finger or a stylus. Touchscreens have been implemented utilizing a number of different technologies, with resistive, acoustic wave, and capacitive touchscreen devices amongst the most widely utilized. Regardless of the particular manner in which the touchscreen is implemented, a touchscreen is typically paired with a display device (referred to herein simply as a “display”), which is positioned immediately beneath and which is visible through the panel of the touchscreen. In one common mode of operation, the display generates a graphic user interface (GUI) including target images (e.g., virtual buttons and other widgets), and the touchscreen monitors for the occurrence of a touch event. When a touch event is detected, the touchscreen, in conjunction with control circuitry included within the handheld electronic device, correlates the location of the touch event with the GUI to determine the desired user input. In other modes of operation, the handheld electronic device may recognize alphanumeric characters drawn on the touchscreen utilizing a stylus.

A stylus is often the preferred means of interfacing with a touchscreen module for several reasons. A stylus tends to transfer less dirt, oil, and other debris to the touchscreen panel. A stylus provides a significantly finer point than does a user's finger and is consequently a more accurate input means. As a result, a stylus can enable a user to interface with a GUI in a more reliable manner and possibly to input alphanumeric characters by drawing the characters on the touchscreen panel as previously described. As a further advantage, a stylus typically provides greater user comfort when utilized over an extended period of time. For these reasons, handheld electronic devices having touchscreen capabilities are often packaged with accompanying styli.

When packaged with a stylus, a handheld electronic device need include a manner in which to store the stylus when not in use. In the majority of cases, a handheld electronic device packaged with an accompanying stylus includes a blind tunnel formed in the device housing for stylus storage. In the case of a handheld electronic device having a clamshell configuration (i.e., wherein first and second housings are hingedly joined together), the blind tunnel is conveniently formed in the hinge joint that rotatably couples the first housing to the second housing. The stylus is longer than the blind tunnel such that, when stored in the blind tunnel, an end portion of the stylus extends through the open end of the tunnel and is thus accessible from the exterior of the device. A detent or other mechanism is usually provided to help retain the stylus within the blind tunnel. To remove the stylus, a user utilizes the tip of his or her finger to engage a hook-like feature provided in the exposed end of the stylus and exert sufficient force on the stylus to overcome the detent. Alternatively, a spring-loaded feature may be provided that enables the user to partially eject the stylus by pressing down on the exposed end thereof.

While generally providing a convenient means for storing styli, blind tunnels and similar retention features are limited in several respects. It can be difficult for certain users, such as elderly users or users having shorter fingernails, to remove a stylus from a blind tunnel using the tip of his or her finger. Although spring-loaded eject features of the type described above can be utilized to facilitate removal of the stylus, such features add undesirable cost and complexity to the handheld electronic device. As a further disadvantage, a stylus is generally hidden from view when stored within a tunnel junction thereby discouraging use of the stylus. With respect to clamshell handheld electronic devices, in particular, the stylus is removable (i.e., the end portion of the stylus is exposed through the opening of the blind tunnel) whether the clamshell device is an open position or a closed position. As a result, the stylus can be accidently dislodged from the clamshell device and lost when not in use. Although a stronger detent can be provided to better retain the stylus and thus decrease the likelihood of loss, the provision of a stronger detent renders removal of the stylus more difficult.

There thus exists an ongoing need to provide embodiments of a handheld electronic device including a novel manner in which to retain a stylus that overcomes the disadvantages associated with conventional stylus storage features, such as blind tunnels. In particular, it would be desirable to provide embodiments of a handheld electronic device including a stylus retaining feature that enables easy removal of the stylus; that presents the stored stylus in a highly visible manner to encourage use of the stylus; and, in the case of a clamshell handheld electronic device, that prevents removal of the stylus when the clamshell is in the closed position to reduce the possibility of accidental loss of the stylus when not in use. Other desirable features and characteristics of the present invention will become apparent from the subsequent Detailed Description and the appended Claims, taken in conjunction with the accompanying Drawings and this Background.

### BRIEF SUMMARY

Embodiments of an electronic device for use in conjunction with a stylus are provided. In one embodiment, the electronic device includes a first housing and a stylus storage groove, which is formed in a surface of the first housing and which is configured to receive the stylus therein. The stylus storage groove enables the stylus to be inserted therein and removed therefrom along an axis substantially orthogonal to the longitudinal axis of the stylus.

### BRIEF DESCRIPTION OF THE DRAWINGS

At least one example of the present invention will hereinafter be described in conjunction with the following figures, wherein like numerals denote like elements, and:

FIGS. 1 and 2 are first and second isometrics view, respectively, of a handheld electronic device including a stylus storage groove in accordance with an exemplary embodiment of the present invention;

FIG. 3 is a cross-sectional view of the handheld electronic device shown in FIGS. 1 and 2 taken through a central portion of the hinge joint and along a plane orthogonal to the hinge line axis; and

FIG. 4 is cross-sectional view of the handheld electronic device shown in FIGS. 1-3 taken through the hinge joint and along a plane parallel to the hinge line axis.

### DETAILED DESCRIPTION

The following Detailed Description is merely exemplary in nature and is not intended to limit the invention or the application and uses of the invention. Furthermore, there is no intention to be bound by any theory presented in the preceding Background or the following Detailed Description.

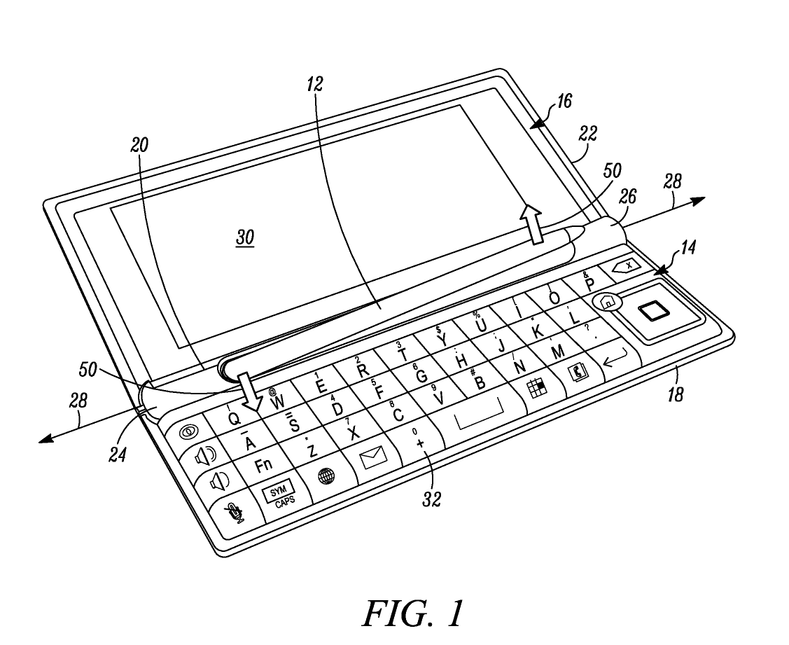

FIGS. 1 and 2 are first and second isometrics view, respectively, of a handheld electronic device 10 including a pop-out stylus 12 in accordance with an exemplary embodiment. As utilized herein, the phrase “pop-out stylus” and similar phrases are utilized to indicate the seesaw-like or lever-action manner in which stylus 12 can be removed from a stylus storage groove formed in a surface of electronic device 10 as described below. The phrase “pop-out stylus” is therefore not utilized to denote any specific characteristics pertaining to the stylus itself; indeed, as appearing herein, the term “stylus” is defined broadly to include any user-manipulated pointing tool or implement having a generally elongated shape and configured to be utilized in conjunction with an electronic device having touchscreen capabilities. Furthermore, although handheld electronic device 10 assumes the form of a personal digital assistant in the illustrated example, it is emphasized that electronic device 10 may assume the form of a smart phone, a personal organizer, a satellite navigation system, a portable gaming system, and various other electronic devices in alternative embodiments.

With reference to the exemplary embodiment illustrated in FIGS. 1 and 2, handheld electronic device 10 includes a first housing 14 and a second housing 16, which is hingedly coupled to first housing 14 in a clamshell configuration. More specifically, first housing 14 includes a first housing body 18 and a barrel 20, which extends longitudinally along a side portion of first housing body 18. Similarly, second housing 16 includes a second housing body 22 and first and second knuckles 24 and 26 spaced apart along a side portion of second housing body 22. When handheld electronic device 10 is assembled, barrel 20 of first housing 14 is received between knuckles 24 and 26 of second housing 16. Barrel 20 is rotatably coupled to knuckle 24 and knuckle 26 utilizing, for example, first and second dowel pins (hidden from view in FIGS. 1 and 2). In this manner, barrel 20 and knuckles 24 and 26 cooperate to form a hinge joint between first housing 14 and second housing 16, which enables second housing 16 to rotate relative to first housing 14 about a hinge line axis 28 between a closed position and an open position (illustrated in FIGS. 1 and 2). If desired, a biasing mechanism, such as a spring-loaded cam (not shown), can be mounted between barrel 20 and knuckle 24 and/or barrel 20 and knuckle 26 to help maintain second housing 16 in the open position and/or in the closed position.

In the illustrated example, that first housing 14 and second housing 16 each have a substantially rectangular planform geometry. Furthermore, first housing 14 and second housing 16 are hingedly joined along the longer sides thereof (commonly referred to as a “landscape orientation”). As will become apparent in the course of the subsequent description, the stylus retaining feature described herein is well-suited for formation in the hinge joint of a clamshell electronic device having a landscape orientation due to the increased length of the barrel relative to the barrel of a clamshell device having a portrait orientation. This notwithstanding, embodiments of the stylus retaining feature described herein can also be utilized in conjunction with clamshell electronic devices having portrait orientations.

Handheld electronic device 10 further includes a touchscreen 30, which is integrated into second housing 16, and a QWERTY keypad 32, which is integrated into first housing 14. As will be readily appreciated, touchscreen 30 enables a user to input data by contacting target areas of touchscreen 30 utilizing his or her finger or stylus 12. A conventional display module (not shown), such as a liquid crystal display device, is mounted beneath touchscreen 30. During operation of handheld electronic device 10, the display module generates target images associated with a graphic user interface (e.g., virtual buttons and other widgets) that indicate which area or areas on touchscreen 30 a user need touch to input desired data. A user may also input data utilizing touchscreen 30 in other manners, as well; e.g., in certain embodiments, a user may be able to draw alphanumeric characters on touchscreen 30 utilizing stylus 12 that are recognizable by control circuitry included within electronic device 10. Touchscreen 30 can comprise any electronic device suitable for receiving input from a user-manipulated stylus in this manner, including resistive, capacitive, and surface acoustic wave devices. Depending upon the particular manner in which touchscreen 30 is implemented, stylus 12 may or may not include electronic components, such as an induction coil, pressure sensors, and the like. QWERTY keypad 32 also provides a well-known and convenient for receiving user input data; however, handheld electronic device 10 is by no means required to include a keypad or any other user input devices in addition to touchscreen 30.

Touchscreen 30 is integrated into second housing 16 and exposed through the inner face thereof, and QWERTY keypad 32 is integrated into first housing 14 and exposed through the inner face thereof. When second housing 16, and more generally handheld electronic device 10, is moved into the open position illustrated in FIGS. 1 and 2, the inner face of second housing 16 and inner face of first housing 14 reside in a side-by-side or open-book orientation thereby by permitting touchscreen 30 and QWERTY keypad 32 to be accessed by a user in a primary use mode. Conversely, when handheld electronic device 10 is moved into a closed position, the inner face of second housing 16 and the inner face of first housing 14 reside in a face-to-face or closed-book orientation. Thus, when electronic device 10 is in a closed position, touchscreen 30 and QWERTY keypad 32 generally cannot be accessed by a user, although a user may still be able to operate certain functions of handheld electronic device 10 in a secondary mode of operation in certain embodiments, such as when handheld electronic device 10 assumes the form of a mobile phone.

As noted in the foregoing section entitled “Background,” it is generally desirable for a handheld electronic device utilized in conjunction with a stylus to provide a convenient means for stylus storage that enables easy removal of the stylus, that presents the stored stylus in a highly visible manner to encourage the use thereof, and that prevents removal of the stylus when the clamshell device is closed to reduce the likelihood of stylus loss. To satisfy these criteria, handheld electronic device 10 further includes a stylus storage groove 40. As shown most clearly in FIG. 2, stylus storage groove 40 generally assumes the form of an elongated recess or depression formed in an external surface of the inner face of first housing 14. More specifically, in the exemplary embodiment illustrated in FIGS. 1 and 2, stylus storage groove 40 comprises an elongated depression formed through an outer circumferential sidewall of barrel 20 of first housing 14. Notably, barrel 20 provides a preferred location for stylus storage groove 40. Barrel 20 is conveniently positioned beneath touchscreen 30. Furthermore, by forming stylus storage groove 40 in barrel 20, the envelope of handheld electronic device 10 can be minimized. This preference notwithstanding, stylus storage groove 40 can be formed at various other locations in either first housing 14 or second housing 16. For example, in certain embodiments, the width of main body 18 of first housing 14 can be increased, and stylus storage groove 40 can be formed in an outer surface of first housing 14 immediately below QWERTY keypad 32. Regardless of the particular location at which stylus storage groove 40 is formed, groove 40 is at least partially, and preferably entirely, covered when second housing 16 is moved into a closed position. Thus, when stored within stylus storage groove 40, stylus 12 is likewise covered when second housing 16 is in the closed position. Consequently, stylus 12 is unlikely to be accidently dislodged and lost when electronic device 10 is not in use or at least not in a primary use mode.

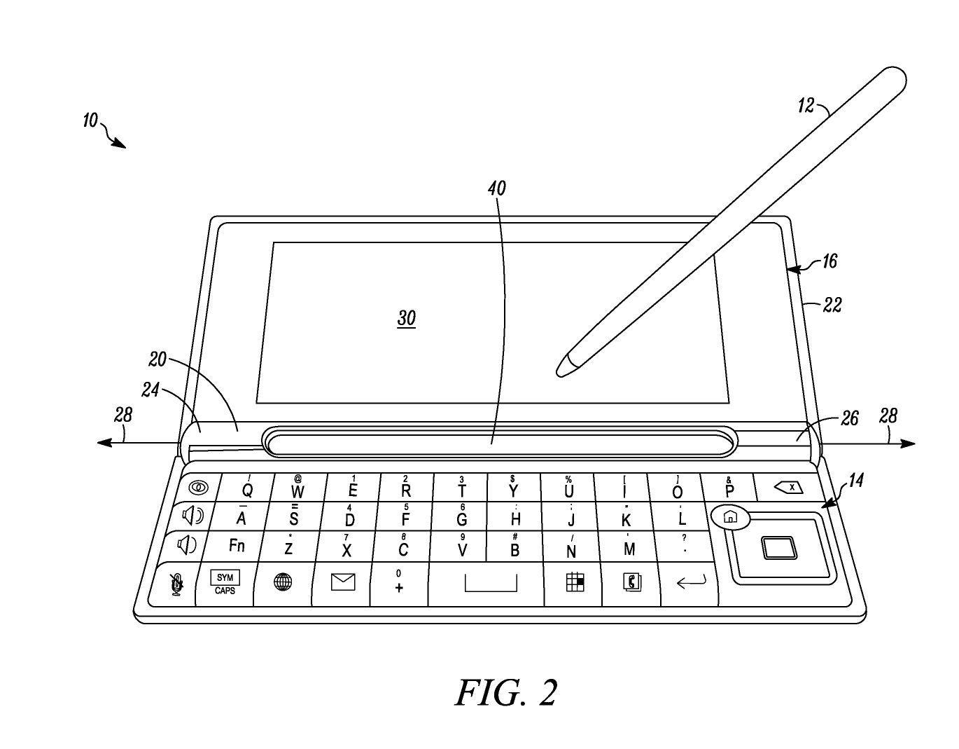

FIG. 3 is a cross-sectional view of handheld electronic device 10 in a closed position taken through a central portion of the hinge joint and along a plane orthogonal to hinge line axis 28 (identified in FIGS. 1 and 2). As indicated in FIG. 3 at 42, a pair of resilient members (e.g., first and second rubber projections) are partially embedded, adhesively attached, and/or otherwise mounted to opposing edges of barrel 20 defining the opening of groove 40. Resilient members 42 have a relatively short length as compared to groove 40 and are preferably centrally disposed within groove 40; however, the disposition and dimensions of resilient members 42, if provided, will inevitably vary amongst different embodiments. Resilient members 42 protrude into the opening of groove 40 and thus interfere with the insertion and removal of stylus 12. When a user initially inserts stylus 12 into groove 40, the body of stylus 12 contacts and deforms resilient members 42 to enable stylus 12 to be received within groove 40. When stylus 12 is fully inserted into groove 40, resilient members 42 return, at least partially, to their non-deformed state to help retain stylus 12 within groove 40. When use of stylus 12 is later desired, a user simply imparts enough force to stylus to again deform resilient members 42 and remove stylus 12 from groove 40 in the manner described below. Of course, other retention means may be utilized to help retain stylus 12 in storage groove 40 in alternative embodiments.

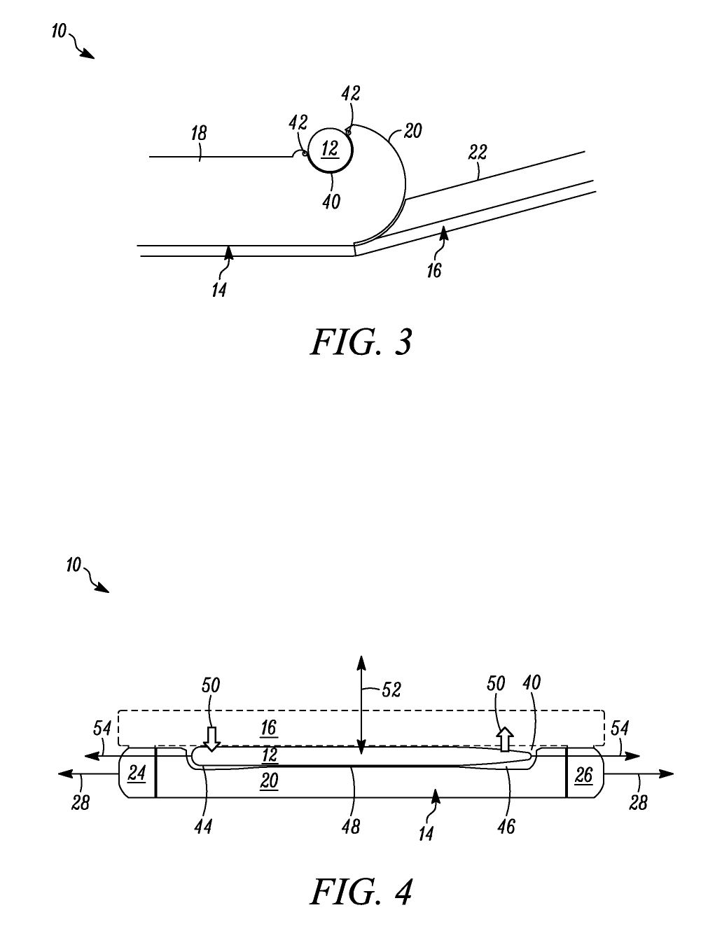

As should be readily apparent, the dimensions of stylus storage groove 40 are preferably chosen to enable stylus 12 to be matingly received within groove 40. The length of groove 40 and the inner diameter of groove 40 may thus be slightly greater than the length and the major outer diameter of stylus 12, respectively. In addition, one or both of the ends portions of stylus storage groove 40 are preferably recessed or sunken relative to the intermediate portion of groove 40 to enable stylus to be removed or “popped-out” utilizing a seesaw-like or lever-action motion. This may be more fully appreciated by referencing to FIG. 4, which is cross-sectional view of handheld electronic device 10 taken through the hinge joint of device 10 and along hinge line axis 28. For clarity, second housing 16 shown in phantom in a closed position in FIG. 4. Referring to FIG. 4 in conjunction with FIGS. 1-3, stylus storage groove 40 includes a first end portion 44 and a second end portion 46, which each taper radially into barrel 20 with increasing distance from the center of groove 40 to form first and second sloping depressions, respectively. Conversely, an intermediate or central portion 48 of groove 40 is raised relative to first end portion 44 and second end portion 46. A user can thus press either end of stylus 12 into stylus storage groove 40 to overcome the retention mechanism (e.g., resilient members 42) and cause the opposing end of the stylus 12 to protrude radially outward from groove 40, as generally indicated in FIGS. 1 and 4 by arrows 50. The user can then easily grasp the protruding end of stylus 12 (e.g., the rightmost end of stylus 12 in the orientation illustrated in FIG. 1) to remove stylus 12 from groove 40. Thus, in a general sense, central portion 48 of groove 40 serves as the fulcrum of a first-class lever; consequently, raised central portion 48 may be referred to as a centrally-located fulcrum herein.

With continued reference to the exemplary embodiment illustrated in FIG. 4, it is preferred that both end portions 44 and 46 of stylus storage groove 40 are depressed relative to the central portion thereof to enable a user to press either end of stylus 12 toward groove 40 (downward in the illustrated orientation) to initiate removal; however, in alternative embodiments, only a single end portion of groove 40 may be depressed. In further embodiments, a central bump or arcuate ridge can be provided in a central portion of groove 40; in such cases, it may still be stated that the end portions of groove 40 are depressed relative to a central or intermediate portion of groove 40, and that groove 40 includes a centrally-located fulcrum. In still further embodiments, groove 40 may have a substantially uniform diameter, and other removal means may be provided, such as a cavity formed adjacent portion of groove 40 and enabling a user to insert the tip of his or her finger under the stored stylus 12.

It should thus be appreciated that stylus 12 can be conveniently inserted into or removed from stylus storage groove 40 when second housing 16 is an open position along an insertion/removal axis 52 (identified in FIG. 4). Notably, insertion/removal axis 52 is substantially orthogonal to the longitudinal axis of stylus 12 (represented in FIG. 4 by line 54) and substantially orthogonal to the longitudinal axis of the stylus storage groove 40. In addition, when stylus storage groove 40 is formed in a component of the hinge joint (e.g., barrel 20), insertion/removal axis 52 is substantially orthogonal to, and possibly substantially co-axial with, hinge line axis 28 (identified in FIGS. 1, 2, and 4).

The foregoing has thus provided an example of a handheld electronic device including a stylus storage groove, which enables easy removal of the stylus utilizing a seesaw-like or lever-action motion and which presents the stored stylus in a highly visible manner to encourage the use thereof. Furthermore, in the case of a clamshell handheld electronic device, the stylus storage groove prevents removal of the stylus when the clamshell is closed to reduce the possibility of accidental loss of the stylus. While the foregoing described a specific exemplary embodiment of a handheld electronic device for the purposes of illustration, embodiments of the invention are equally applicable to various other types of electronic devices having touchscreen capabilities, regardless of the particular form assumed by the electronic device.

While multiple exemplary embodiments have been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention. It being understood that various changes may be made in the function and arrangement of elements described in an exemplary embodiment without departing from the scope of the invention as set-forth in the appended Claims.

What is claimed is:

1. An electronic device for use in conjunction with a stylus, comprising:
a first housing; and
a stylus storage groove formed in a surface of the first housing and configured to receive the stylus therein, the stylus storage groove enabling the stylus to be inserted therein and removed therefrom along an axis substantially orthogonal to the longitudinal axis of the stylus.

2. An electronic device according to claim 1 further comprising a second housing hingedly coupled to the first housing and rotatable relative thereto about a hinge line axis between an open position and a closed position.

3. An electronic device according to claim 2 wherein the stylus storage groove is configured to enable insertion and removal of the stylus along an axis substantially orthogonal to the hinge line axis.

4. An electronic device according to claim 2 wherein the stylus storage groove is exposed when the second housing is in the open position and substantially covered by the second housing when the second housing is in the closed position.

5. An electronic device according to claim 2 wherein the stylus storage groove is configured to enable insertion and removal of the stylus along an axis substantially orthogonal to the longitudinal axis of the stylus storage groove.

6. An electronic device according to claim 2 wherein the stylus storage groove comprises an elongated recess formed in an inner face of the first housing.

7. An electronic device according to claim 2 further comprising a keypad integrated into the first housing, the stylus storage groove formed adjacent the keypad.

8. An electronic device according to claim 2 wherein the stylus storage groove is formed in the first housing proximate the region of the first housing hingedly coupled to the second housing.

9. An electronic device according to claim 2 wherein the first housing includes a barrel hingedly coupled to the second housing, the stylus storage groove formed in the barrel.

10. An electronic device according to claim 9 wherein the stylus storage groove is formed through an outer circumferential sidewall of the barrel.

11. An electronic device according to claim 10 wherein the first housing and the second housing are rotatably coupled in a landscape configuration.

12. An electronic device according to claim 2 wherein the stylus storage groove comprises a substantially centrally-located fulcrum to enable the stylus to be removed from the stylus storage groove utilizing a lever-action motion.

13. An electronic device according to claim 2 wherein the stylus storage groove comprises a first depressed end portion, a second depressed end portion substantially opposite the first depressed end portion, and a raised intermediate portion between the first depressed end portion and the second depressed end portion.

14. An electronic device according to claim 2 further comprising a retention feature coupled to the first housing proximate the stylus storage groove and engaging the stylus when in the stylus storage groove to help retain the stylus therein.

15. An electronic device according to claim 14 wherein the retention feature comprises a resilient member mounted to the first housing and projecting into the opening of the stylus storage groove.

16. An electronic device for use in conjunction with a stylus, comprising:
a first housing including a barrel;
a second housing including first and second knuckles rotatably coupled to opposing end portions of the barrel, respectively; and
a stylus storage groove formed in a circumferential sidewall of the barrel between the first and second knuckles and configured to receive the stylus therein.

17. An electronic device according to claim 16 wherein the second housing is rotatable relative to the first housing about a hinge line axis, and wherein the longitudinal axis of the stylus storage groove is substantially co-axial with the hinge line axis.

18. An electronic device for use in conjunction with a stylus, comprising:
a first housing;
a second housing hingedly coupled to the first housing and rotatable relative thereto between an open position and a closed position; and
a stylus storage groove provided in the first housing and configured to receive the stylus therein, the stylus storage groove exposed when the second housing is in the open position and covered when the second housing is in the closed position.

19. An electronic device according to claim 18 wherein the stylus storage groove comprises an elongated recess formed in the inner face of the first housing.

20. An electronic device according to claim 18 wherein the stylus storage groove comprises:
a first recessed end portion; and
a raised intermediate portion cooperating with the first recessed end portion to enable removal of the stylus utilizing a lever-action motion.
